(19) United States
(12) Patent Application Publication
(10) Pub. No.: US 2026/0349328 A1
(43) Pub. Date: Nov. 5, 2026

(54) REFLECTIVE MASK BLANK, REFLECTIVE MASK, METHOD FOR MANUFACTURING REFLECTIVE MASK BLANK, AND METHOD FOR MANUFACTURING REFLECTIVE MASK

(71) Applicant: AGC Inc., Tokyo (JP)

(72) Inventors: Mitsutaka MATSUMOTO, Koriyama-shi (JP); Sadatatsu IKEDA, Koriyama-shi (JP)

(73) Assignee: AGC Inc., Tokyo (JP)

(21) Appl. No.: 19/634,200

(22) Filed: Mar. 31, 2026

Related U.S. Application Data
(63) Continuation of application No. PCT/JP2024/032153, filed on Sep. 9, 2024.

(30) Foreign Application Priority Data
Oct. 10, 2023 (JP) 2023-174933

(51) Int. Cl. G03F 1/54; G03F 1/24; G03F 1/48

(52) U.S. Cl. CPC G03F 1/54; G03F 1/24; G03F 1/48

(57) ABSTRACT

A reflective mask blank includes a substrate, a multilayer reflective film that reflects EUV light, a protective film that protects the multilayer reflective film, and an absorbing film that absorbs EUV light, in that order. The protective film includes a Ru compound, and the Ru compound includes Ru, Si, and O.

### CROSS-REFERENCE TO RELATED APPLICATION

This application is a continuation application of International Application No. PCT/JP2024/032153, filed on Sep. 9, 2024, which claims the benefit of priority of the prior Japanese Patent Application No. 2023-174933, filed on Oct. 10, 2023 in Japan, the content of which are incorporated herein by reference.

### TECHNICAL FIELD

The present disclosure relates to a reflective mask blank, a reflective mask, a method for manufacturing a reflective mask blank, and a method for manufacturing a reflective mask.

### BACKGROUND ART

In recent years, with the miniaturization of semiconductor devices, EUV lithography (EUVL), which is an exposure technology using extreme ultra-violet (EUV) rays, has been developed. EUV includes soft X-rays and vacuum ultraviolet rays, and specifically refers to light with a wavelength of approximately 0.2 nm to 100 nm. At present, EUV with a wavelength of approximately 13.5 nm is mainly being considered.

In EUVL, a reflective mask is used. The reflective mask has, for example, a glass substrate, a multilayer reflective film, a protective film, and an absorbing film, in that order. The multilayer reflective film reflects EUV light. The protective film protects the multilayer reflective film from an etching gas during processing of the absorbing film. The absorbing film absorbs EUV light. The absorbing film may not only absorb EUV light but also shift the phase of EUV light. That is, the absorbing film may be a phase shift film. In EUVL, an opening pattern of the absorbing film is transferred onto a target substrate such as a semiconductor substrate. Transferring includes transferring with reduction.

In a reflective mask blank described in Patent Document 1, a protective film is made of a Ru compound containing Ru and X (X is at least one selected from Nb and Zr). This protective film has an oxide layer including X as a main component in a surface layer opposite a substrate of the protective film for the purpose of improving resistance to ozone water and improving resistance to an etching gas (including 70% or more oxygen and including a chlorine-based gas).

In a reflective mask blank described in Patent Document 2, a protective film is made of a Ru-based material, and a phase shift film is made of a Ta-based material. A diffusion prevention layer is formed on a surface of the protective film (a surface in contact with the phase shift film). The diffusion prevention layer includes Ru and O and inhibits interdiffusion between the protective film and the phase shift film.

### RELATED ART DOCUMENT

### Patent Document

Patent Document 1: Japanese Unexamined Patent Application, First Publication No. 2010-092947
Patent Document 2: Japanese Unexamined Patent Application, First Publication No. 2015-122468

### SUMMARY

### Problems to be Solved by the Invention

A protective film of a reflective mask blank may include Ru. When the protective film including Ru is crystallized, an absorbing film may inherit the crystalline structure of the protective film, which may cause the absorbing film to be crystallized. As a result, an opening pattern is formed along the crystal grain boundaries of the absorbing film, which may cause the opening pattern to become rough.

One aspect of the present disclosure provides a technology for suppressing crystallization of a protective film of a reflective mask blank in a case in which the protective film includes Ru.

### Means for Solving the Problem

A reflective mask blank according to one aspect of the present disclosure includes a substrate, a multilayer reflective film that reflects EUV light, a protective film that protects the multilayer reflective film, and an absorbing film that absorbs EUV light, in that order. The protective film includes a Ru compound, and the Ru compound includes Ru, Si, and O.

### Advantage of the Invention

According to one aspect of the present disclosure, it is possible to suppress crystallization of a protective film of a reflective mask blank in a case in which the protective film includes Ru.

### BRIEF DESCRIPTION OF THE DRAWINGS

FIG. 1 A cross-sectional view showing a reflective mask blank according to one embodiment.

FIG. 2 A flowchart showing a method for manufacturing a reflective mask blank according to one embodiment.

FIG. 3 A cross-sectional view showing a reflective mask according to one embodiment.

FIG. 4 A flowchart showing a method for manufacturing a reflective mask according to one embodiment.

FIG. 5 FIG. 5(A) being a cross-sectional view showing an example of S201, FIG. 5(B) being a cross-sectional view showing an example of S202, and FIG. 5(C) being a cross-sectional view showing an example of S203.

FIG. 6 A cross-sectional view showing an example of EUV light reflected by the reflective mask of FIG. 3.

FIG. 7 FIG. 7A being a diagram showing a TEM image of a reflective mask blank according to Example 1 and FIG. 7B being the distribution of each element thereof measured using TEM-EDX.

FIG. 8 FIG. 8A being a diagram showing a TEM image of a reflective mask blank according to Example 5 and FIG. 8B being the distribution of each element thereof measured using TEM-EDX.

### DESCRIPTION OF THE EMBODIMENTS

Hereinafter, embodiments of the present disclosure will be described with reference to the drawings. In each drawing, the same or corresponding constituent elements are designated by the same reference signs, and the description thereof may be omitted. In this specification, the use of“to” indicating a numerical range means that the numerical values described before and after “to” are included as a lower limit value and an upper limit value. The numerical range includes a range obtained by rounding off.

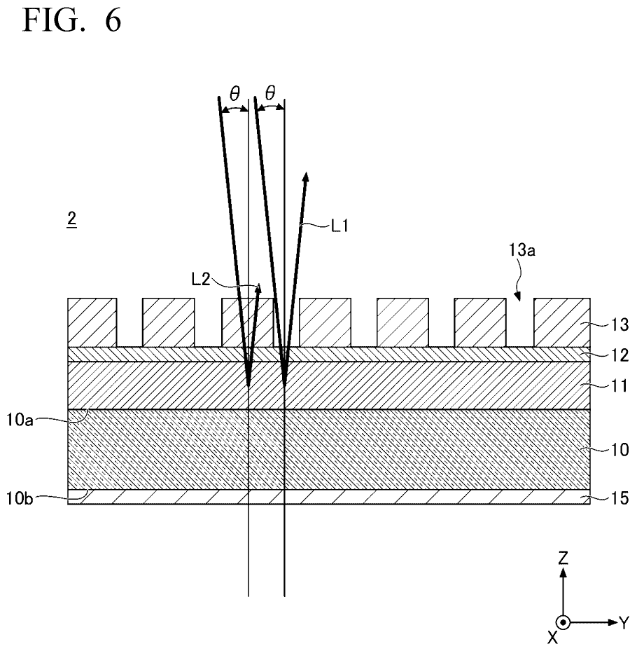

In each drawing, an X-axis direction, a Y-axis direction, and a Z-axis direction are orthogonal to each other. The Z-axis direction is a direction perpendicular to a first main surface 10a of a substrate 10. The X-axis direction is a direction orthogonal to a surface of incidence of EUV light (a surface including an incident light ray and a reflected light ray). As shown in FIG. 6, the incident light ray is inclined in a positive Y-axis direction as it travels in a negative Z-axis direction, and the reflected light ray is inclined in the positive Y-axis direction as it travels in the positive Z-axis direction.

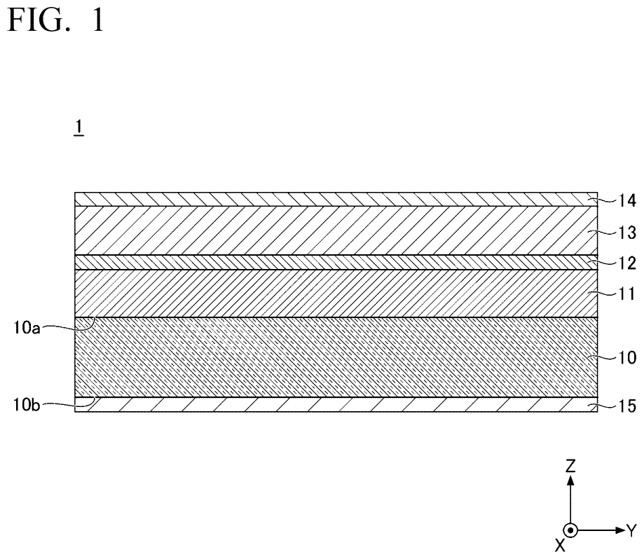

A reflective mask blank 1 according to one embodiment will be described with reference to FIG. 1. The reflective mask blank 1 has, for example, a substrate 10, a multilayer reflective film 11, a protective film 12, an absorbing film 13, and a hard mask film 14, in that order. The multilayer reflective film 11, the protective film 12, the absorbing film 13, and the hard mask film 14 are on the first main surface 10a of the substrate 10 formed, in that order. The multilayer reflective film 11 reflects EUV light. The protective film 12 protects the multilayer reflective film 11 from a first etching gas during processing of the absorbing film 13. The absorbing film 13 absorbs EUV light. The absorbing film 13 may not only absorb EUV light but also shift the phase of EUV light. That is, the absorbing film 13 may be a phase shift film. The hard mask film 14 protects a part of the absorbing film 13 from the first etching gas during processing of the absorbing film 13.

The reflective mask blank 1 may have a conductive film 15 on a side of the substrate 10 opposite to the multilayer reflective film 11. That is, the reflective mask blank 1 may have the conductive film 15, the substrate 10, the multilayer reflective film 11, the protective film 12, the absorbing film 13, and the hard mask film 14, in that order. The conductive film 15 is formed on a second main surface 10b of the substrate 10. The second main surface 10b is a surface on a side opposite to the first main surface 10a. The conductive film 15 is used, for example, to adsorb a reflective mask 2 to an electrostatic chuck of an exposure device.

The reflective mask blank 1 may further have a functional film not shown in FIG. 1. For example, the reflective mask blank 1 may have a diffusion barrier film (not shown) between the multilayer reflective film 11 and the protective film 12. The diffusion barrier film prevents metal elements included in the protective film 12 from diffusing into the multilayer reflective film 11.

Although it is not shown, the reflective mask blank 1 may have a buffer film between the protective film 12 and the absorbing film 13. The buffer film protects the protective film 12 from the first etching gas for forming an opening pattern 13a in the absorbing film 13. The buffer film is etched more slowly than the absorbing film 13. Unlike the protective film 12, the buffer film will ultimately have the same opening pattern as the opening pattern 13a of the absorbing film 13.

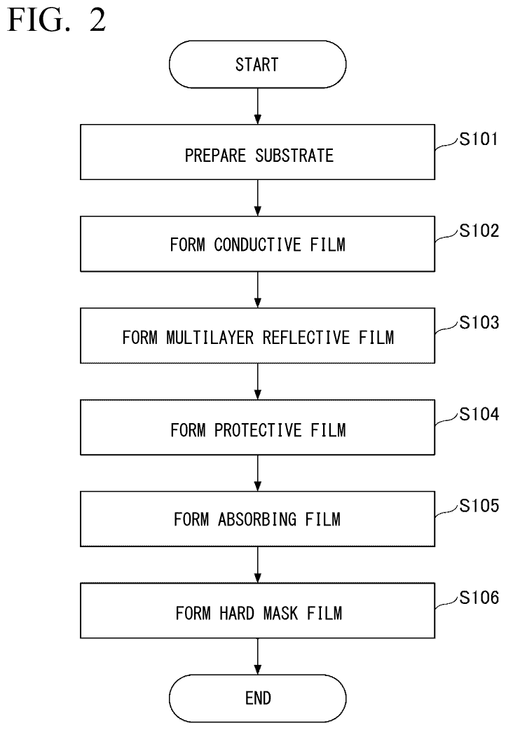

Next, a method for manufacturing the reflective mask blank 1 according to one embodiment will be described with reference to FIG. 2. The method for manufacturing the reflective mask blank 1 includes, for example, steps S101 to S106 shown in FIG. 2. In step S101, the substrate 10 is prepared. In step S102, the conductive film 15 is formed on the second main surface 10b of the substrate 10. In step S103, the multilayer reflective film 11 is formed on the first main surface 10a of the substrate 10. In step S104, the protective film 12 is formed on the multilayer reflective film 11. In step S105, the absorbing film 13 is formed on the protective film 12. In step S106, the hard mask film 14 is formed on the absorbing film 13.

The order of steps S101 to S106 is not limited to the order shown in FIG. 2. For example, the order of step S102 and steps S103 to S106 may be reversed. In addition, the method for manufacturing the reflective mask blank 1 does not necessarily have to include all of steps S101 to S106. The method for manufacturing the reflective mask blank 1 may further include a step of forming a functional film not shown in FIG. 2.

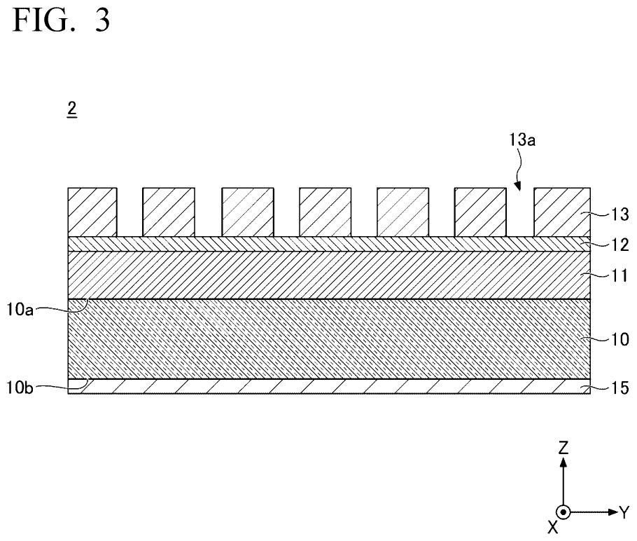

Next, the reflective mask 2 according to one embodiment will be described with reference to FIG. 3. The reflective mask 2 is produced using, for example, the reflective mask blank 1 shown in FIG. 1, and includes the opening pattern 13a in the absorbing film 13. In EUVL, the opening pattern 3a of the absorbing film 13 is transferred onto a target substrate such as a semiconductor substrate. Transferring includes transferring with reduction. The hard mask film 14 shown in FIG. 1 is not included in the reflective mask 2.

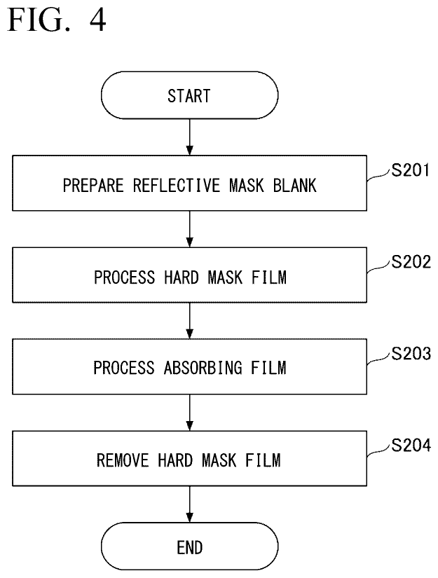

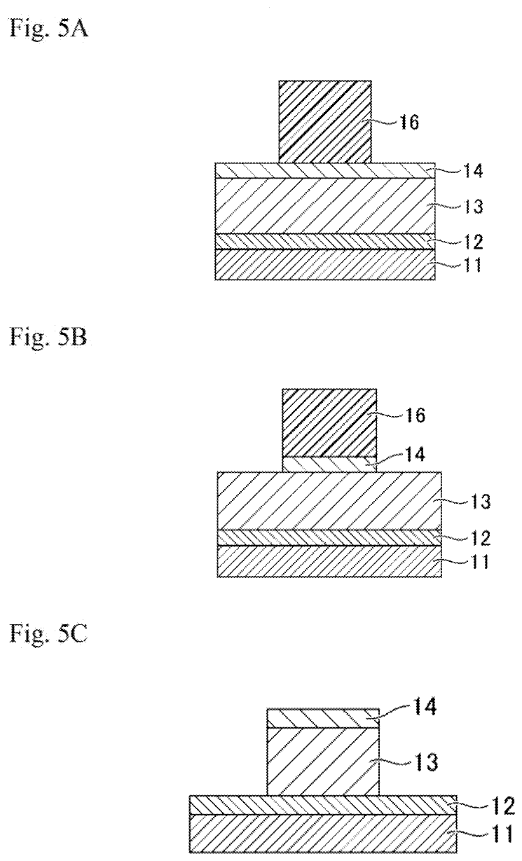

Next, a method for manufacturing the reflective mask 2 according to one embodiment will be described with reference to FIGS. 4 and 5. The method for manufacturing the reflective mask 2 includes steps S201 to S204 shown in FIG. 4. In step S201, as shown in FIG. 5(A), the reflective mask blank 1 is prepared. The reflective mask blank 1 includes a resist film 16 as shown in FIG. 5(A). The resist film 16 is formed on the hard mask film 14. The resist film 16 has an opening pattern formed therein to be transferred to the absorbing film 13.

In step S202, as shown in FIG. 5(B), the hard mask film 14 is processed using the resist film 16 having the opening pattern. At an opening of the resist film 16, the hard mask film 14 is exposed to a second etching gas, and the second etching gas etches the hard mask film 14. At the end of step S202, the resist film 16 remains. As a result, the opening pattern of the resist film 16 is transferred to the hard mask film 14.

The second etching gas is selected depending on a combination of a material of the resist film 16 and a material of the hard mask film 14, and is not particularly limited, but includes, for example, a fluorine-based gas. The fluorine-based gas includes at least one selected from, for example, CF₄ gas, CHF₃ gas, C₂F₆ gas, C₃F₆ gas, C₄F₆ gas, C₄F₈ gas, CH₂F₂ gas, CH₃F gas, CF₈ gas, F₂ gas, SF₆ gas, and NF₃ gas. The second etching gas may include an active gas or an inert gas in addition to the fluorine-based gas. The active gas includes, for example, O₂ gas. The inert gas includes at least one selected from, for example, N₂ gas, He gas, and Ar gas. The second etching gas is preferably in the form of plasma.

In step S203, as shown in FIG. 5(C), the absorbing film 13 is processed using the hard mask film 14 having the opening pattern. At an opening of the hard mask film 14, the absorbing film 13 is exposed to the first etching gas, and the first etching gas etches the absorbing film 13. The hard mask film 14 has higher resistance to the first etching gas than the absorbing film 13. At the end of step S203, the hard mask film 14 remains. As a result, the opening pattern of the hard mask film 14 is transferred to the absorbing film 13.

The first etching gas is selected depending on a combination of a material of the hard mask film 14 and a material of the absorbing film 13, and is not particularly limited, but includes, for example, a chlorine-based gas and an oxygen-based gas. The chlorine-based gas includes at least one selected from, for example, Cl₂ gas, SiCl₄ gas, CHCl₃ gas, CCl₄ gas, and BCl₃ gas. The oxygen-based gas includes at least one selected from, for example, O₂ gas and O₃ gas. The first etching gas may include an inert gas in addition to the chlorine-based gas and the oxygen-based gas. The inert gas includes at least one selected from, for example, N₂ gas, He gas, and Ar gas. The first etching gas is preferably in the form of plasma.

In step S204, although it is not shown, the hard mask film 14 is removed. In order to remove the hard mask film 14, for example, a third etching gas is used. The third etching gas includes, for example, a fluorine-based gas, similar to the second etching gas. The third etching gas is preferably in the form of plasma. In order to remove the hard mask film 14, a chemical solution may be used.

Next, referring back to FIG. 1, the substrate 10, the multilayer reflective film 11, the protective film 12, the absorbing film 13, the hard mask film 14, and the conductive film 15 will be described in that order.

The substrate 10 is, for example, a glass substrate. The material of the substrate 10 is preferably quartz glass containing TiO₂. The quartz glass has a smaller coefficient of linear expansion and is less susceptible to a dimensional change due to a temperature change than the common soda-lime glass. The quartz glass may include 80% by mass to 95% by mass of SiO₂ and 4% by mass to 17% by mass of TiO₂. When the TiO₂ content is 4% by mass to 17% by mass, the coefficient of linear expansion is approximately zero at around room temperature, and there is almost no dimensional change at around room temperature. The quartz glass may contain a third component or impurities other than SiO₂ and TiO₂. The material of the substrate 10 may be crystallized glass in which a β-quart solid solution is precipitated, silicon, a metal, or the like.

The substrate 10 has the first main surface 10a and a second main surface 10b on a side opposite to the first main surface 10a. The multilayer reflective film 11 and the like are formed on the first main surface 10a. The size of the substrate 10 in a plan view (viewed in the Z-axis direction) is, for example, 152 mm in length and 152 mm in width. Each of the length dimension and the width dimension may be 152 mm or more. The first main surface 10a and the second main surface 10b each have, for example, a square quality assurance area at the center thereof. The size of the quality assurance area is, for example, 142 mm in length and 142 mm in width. Each of the length dimension and the width dimension may be 142 mm or more. The quality assurance area of the first main surface 10a preferably has a root mean square roughness (Rq) of 0.15 nm or less and a flatness of 100 nm or less. In addition, it is preferable that the quality assurance area of the first main surface 10a does not have any defects that cause a phase defect.

The multilayer reflective film 11 reflects EUV light. The multilayer reflective film 11 is, for example, a film obtained by stacking high refractive index layers and low refractive index layers alternately. The material of the high refractive index layer is, for example, silicon (Si), and the material of the low refractive index layer is, for example, molybdenum (Mo), and thus a Mo/Si multilayer reflective film is used. In addition, a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo/Ru multilayer reflective film, a Si/Ru/Mo multilayer reflective film, or the like can also be used as the multilayer reflective film 11.

The film thickness of each layer constituting the multilayer reflective film 11 and the number of repeating units of each layer can be appropriately selected depending on the material of each layer and the reflectance for EUV light. In a case in which the multilayer reflective film 11 is a Mo/Si multilayer reflective film, in order to achieve a reflectance of 60% or more with respect to EUV light having an incidence angle θ (see FIG. 6) of 6°, a Mo layer having a film thickness of 2.3±0.1 nm and a Si layer having a film thickness of 4.5±0.1 nm may be stacked so that the number of repeating units is 30 or more and 60 or less. The multilayer reflective film 11 preferably has a reflectance of 60% or more with respect to EUV light having an incidence angle θ of 6°. The reflectance is more preferably 65% or more.

A film formation method for each layer constituting the multilayer reflective film 11 is, for example, a DC sputtering method, a magnetron sputtering method, an ion beam sputtering method, or the like. In a case in which the Mo/Si multilayer reflective film is formed using an ion beam sputtering method, an example of film formation conditions for each of the Mo layer and the Si layer is as follows.

### <Film Formation Conditions for Si Layer>

Target: Si target
Sputtering gas: Ar gas
Gas pressure: 1.3×10⁻² Pa to 2.7×10⁻² Pa
ion acceleration voltage: 300 V to 1500 V
Film formation rate: 0.030 nm/sec to 0.300 nm/sec
Film thickness of Si layer: 4.5-0.1 nm

### <Film Formation Conditions for Mo Layer>

Target: Mo target
Sputtering gas: Ar gas
Gas pressure: 1.3×10⁻² Pa to 2.7×10⁻² Pa
Ion acceleration voltage: 300 V to 1500 V
Film formation rate: 0.030 nm/sec to 0.300 nm/sec
Film thickness of Mo layer: 2.3±0.1 nm

### <Repeating Unit of Si Layer and Mo Layer>

The number of repeating units: 30 to 60 (preferably 40 to 50)

The protective film 12 is formed between the multilayer reflective film 11 and the absorbing film 13 to protect the multilayer reflective film 11. The protective film 12 protects the multilayer reflective film 11 from the first etching gas during processing of the absorbing film 13, that is, in step S203. The protective film 12 is not removed even when exposed to the first etching gas, and remains on the multilayer reflective film 11.

In a case in which the protective film 12 includes Ru, it may exhibit crystallinity. When the protective film 12 is crystallized, the absorbing film 13 may inherit the crystalline structure of the protective film 12, which may cause the absorbing film 13 to be crystallized. As a result, the opening pattern 13a is formed along the crystal grain boundaries of the absorbing film 13, which may cause the opening pattern 13a to become rough.

The protective film 12 of the present embodiment includes a Ru compound, and the Ru compound includes Ru, Si, and O. Si is more easily oxidized than Ru, and can increase an O concentration in the Ru compound. O suppresses the crystallization of Ru. Therefore, the crystallization of the protective film 12 can be suppressed, and further, the crystallization of the absorbing film 13 can be suppressed.

It is more preferable that the Ru compound constituting the protective film 12 has an average value of a Si concentration of 9.0 at % or more. If the average value of the Si concentration is 9.0 at % or more, the O concentration in the Ru compound is easily increased, and the crystallization of Ru is easily suppressed. The average value of the Si concentration is more preferably 9.5 at % or more, even more preferably 10.0 at % or more, and particularly preferably 15.0 at % or more.

It is preferable that the Ru compound constituting the protective film 12 have an average value of a Si concentration of less than 37.9 at %. If the average value of the Si concentration is less than 37.9 at %, the O concentration is not too high, and the generation of a defect including SiO can be suppressed. The generation of the defect including SiO causes the surface of the protective film 12 to become rough. The average value of the Si concentration is more preferably 37.0 at % or less, even more preferably 35.0 at % or less, and particularly preferably 25.0 at % or less.

It is preferable that the Ru compound constituting the protective film 12 have an average value of an O concentration of 3.0 at % or more. If the average value of the O concentration is 3.0 at % or more, O can easily suppress the crystallization of Ru. The average value of the O concentration is more preferably 3.5 at % or more, and even more preferably 5.0 at % or more.

It is preferable that the Ru compound constituting the protective film 12 have an average value of an O concentration of less than 12.6 at %. If the average value of the O concentration is less than 12.6 at %, the O concentration is not too high, and the generation of the defect including SiO can be suppressed. The generation of the defect including SiO causes the surface of the protective film 12 to become rough. The average value of the O concentration is more preferably 10.0 at % or less, and even more preferably 8.0 at % or less.

The protective film 12 includes, for example, a RuSiO film. The RuSiO film can be obtained, for example, by first forming a RuSi film and then oxidizing the RuSi film. The oxidation of the RuSi film begins from the surface of the RuSi film. Therefore, as the depth from the surface of the RuSiO film is increased, the O concentration is lowered. The O concentration also depends on the element ratio of Ru to Si. Si is more easily oxidized than Ru, and thus, as the Si concentration is increased, the O concentration is increased.

The RuSi film is formed by, for example, dual-target sputtering. The element ratio of Ru to Si can be adjusted by controlling the power density of each of the Ru target and the Si target. The element ratio of Ru to Si may be made constant regardless of the depth, the element ratio of Ru to Si may be graded, or the Si concentration may be increased only in the outermost layer. Oxidation of the RuSi film includes, for example, irradiating the RuSi film with oxygen plasma or implanting oxygen ions into the RuSi film.

The RuSiO film can also be formed using a reactive sputtering method. In this case, the element ratio of Ru to Si can be adjusted by controlling the power density of each of the Ru target and the Si target. In addition, the O concentration can be adjusted by controlling the volume ratio of O₂ gas in the sputtering gas (O₂(Ar+O₂)). The O concentration is constant, for example, regardless of the depth from the surface of the RuSiO film. It is also possible to grade the O concentration in a depth direction, or to oxidize only the outermost layer.

In the present embodiment, the protective film 12 is a film made of a single layer, but it may be a multilayer film having a lower layer and an upper layer. The lower layer of the protective film 12 is a layer formed in contact with the uppermost surface of the multilayer reflective film 11. The upper layer of the protective film 12 is in contact with the lowermost surface of the absorbing film 13. In this manner, by forming the protective film 12 as a multilayer structure, a material having an excellent predetermined function can be used for each layer, and therefore the protective film 12 as a whole can be made multifunctional.

The upper layer of the protective film 12 preferably includes at least one element selected from Ru and Rh, more preferably includes Rh, and even more preferably includes an Rh compound. The lower layer of the protective film 12 preferably includes at least one element selected from Ru, Rh, Nb, Mo, Zr, Y, and Si, more preferably includes Ru, and even more preferably includes the above-described Ru compound. In a case in which the protective film 12 is a multilayer film, the thickness of the protective film 12, which will be described below, means the total film thickness of the multilayer film. A mixed layer formed by mixing the components included in the multilayer reflective film 11 and the components included in the lower layer of the protective film 12 may be formed between the multilayer reflective film 11 and the lower layer of the protective film 12.

The thickness of the protective film 12 is preferably 1.0 nm to 7.0 nm, more preferably 2.0 nm to 6.5 nm, and even more preferably 2.5 nm to 6.5 nm. If the thickness of the protective film 12 is 1.0 nm or more, the etching resistance is good. In addition, if the thickness of the protective film 12 is 7.0 nm or less, the reflectance for EUV light is good.

The density of the protective film 12 is preferably 10.0 g/cm³ to 14.0 g/cm³. If the density of the protective film 12 is 10.0 g/cm³ or more, the etching resistance is good. In addition, if the density of the protective film 12 is 14.0 g/cm³ or less, the decrease in reflectance for EUV light can be suppressed.

The upper surface of the protective film 12, that is, the surface of the protective film 12 on which the absorbing film 13 is to be formed, has a root mean square roughness Rq of preferably 0.20 nm or less, more preferably 0.17 nm or less. If the root mean square roughness Rq is 0.20 nm or less, the absorbing film 13 and the like can be formed smoothly on the protective film 12. In addition, scattering of EUV light can be suppressed, and the reflectance for EUV light can be improved. The root mean square roughness Rq is preferably 0.05 nm or more.

A film formation method for the protective film 12 is, for example, a DC sputtering method, a magnetron sputtering method, an ion beam sputtering method, or the like. In a case in which the RuSi film is formed using a DC sputtering method and subsequently the RuSi film is oxidized, an example of the film formation conditions is as follows.

### <Film Formation Conditions for RuSi Film>

Target: Ru target and Si target
Sputtering gas: Ar gas
Gas pressure: 1.0×10⁻² Pa to 1.0×10⁰ Pa
Power density of target: 1.0 W/cm² to 8.5 W/cm²
Film formation rate: 0.020 nm/sec to 1.000 nm/sec
Film thickness: 1 nm to 10 nm

### <Oxidation Conditions (Plasma Treatment Conditions) for RuSi Film>

O₂ gas flow rate: 200 sccm to 3000 sccm
Ar gas flow rate: 100 sccm to 6000 sccm
Ratio of O₂ gas in a mixed gas of O₂ gas and Ar gas: 0% by volume to 90% by volume
Power supply frequency for plasma generation: 10 MHz to 60 MHz
Electric power for plasma generation: 50 W to 600 W
Treatment time: 2 sec to 120 sec
Treatment temperature: 80 °C to 350 °C
Treatment pressure: 50 Pa to 1200 Pa

The absorbing film 13 absorbs EUV light. The absorbing film 13 is a film in which the opening pattern 13a is to be formed. The opening pattern 13a is not formed in the manufacturing process of the reflective mask blank 1, but is formed in the manufacturing process of the reflective mask 2. The absorbing film 13 may not only absorb EUV light but also shift the phase of EUV light. That is, the absorbing film 13 may be a phase shift film. The phase shift film shifts the phase of second EUV light L2 relative to first EUV light L1 shown in FIG. 6.

The first EUV light L1 is light that passes through the opening pattern 13a without being transmitted through the absorbing film 13, is reflected by the multilayer reflective film 11, and passes through the opening pattern 13a without being transmitted through the absorbing film 13 again, ne second EUV light L2 is light that is transmitted through the absorbing film 13 while being absorbed by the absorbing film 13, is reflected by the multilayer reflective film 11, and is transmitted through the absorbing film 13 while being absorbed by the absorbing film 13 again.

A phase difference (>0) between the first EUV light L1 and the second EUV light L2 is, for example, 170° to 250°. The phase of the first EUV light L1 may be advanced or delayed relative to the phase of the second EUV light L2. The absorbing film 13 utilizes interference between the first EUV light L1 and the second EUV light L2 to improve the contrast of a transferred image. The transferred image is an image obtained by transferring the opening pattern 13a of the absorbing film 13 onto the target substrate.

In EUVL, a so-called shadowing effect occurs. The shadowing effect refers to the occurrence of an area near a side wall of the opening pattern 13a where the side wall blocks EUV light due to the incidence angle θ of EUV light being not 0° (for example, 6°), resulting in a positional deviation or a dimensional deviation of the transferred image. In order to reduce the shadowing effect, it is effective to lower the height of the side wall of the opening pattern 13a, and it is also effective to make the absorbing film 13 thinner.

The film thickness of the absorbing film 13 is, for example, 60 nm or less, and preferably 50 nm or less, in order to reduce the shadowing effect. The film thickness of the absorbing film 13 is preferably 20 nm or more, and more preferably 30 nm or more, in order to ensure a phase difference between the first EUV light L and the second EUV light L2.

In order to decrease the film thickness of the absorbing film 13 for reducing the shadowing effect while ensuring the phase difference between the first EUV light L1 and the second EUV light L2, it is effective to decrease the refractive index n of the absorbing film 13. In addition, in order to decrease the reflectance for EUV light, it is effective to increase the extinction coefficient k of the absorbing film 13. In this manner, the absorbing film 13 is required to have excellent optical properties.

The absorbing film 13 preferably includes at least one metal element selected from Cr, Ta, Nb, Ir, Pt, Pd, Au, and Ru. These metal elements have a relatively small refractive index, and therefore it is possible to decrease the film thickness of the absorbing film 13 while ensuring a phase difference. The absorbing film 13 preferably includes a compound of the metal element. The compound of the metal element preferably includes at least one element selected from O, B, C, Si, and N. By adding at least one element selected from O, B, C, Si, and N, it is possible to suppress crystallization while suppressing deterioration of the optical properties, and to decrease the roughness of the opening pattern 13a. The absorbing film 13 more preferably includes a Ta compound. The Ta compound more preferably includes N. This is because the inclusion of N can suppress the crystallization of the Ta compound, and prevent surface roughening due to the crystallization. The absorbing film 13 preferably includes TaN.

In the present embodiment, the absorbing film 13 is a film made of a single layer, but it may be a multilayer film having a lower layer and an upper layer. The lower layer and the upper layer that constitute the absorbing film 13 are formed on the protective film 12, in that order. The uppermost layer of the absorbing film 13 is a layer farthest from the protective film 12. The uppermost layer of the absorbing film 13 preferably includes at least one metal element selected from Cr, Ta, Nb, Ir, Pt, Pd, Au, and Ru, and more preferably includes a compound of the metal element. The uppermost layer of the absorbing film 13 more preferably includes a Ta compound. The Ta compound is more preferable because it includes N, which suppresses the crystallization of Ta and prevents the crystals from becoming large and increasing the surface roughness. That is, the absorbing film 13 preferably includes TaN. In a case in which the absorbing film 13 is a multilayer film, the thickness of the absorbing film 13 means the total film thickness of the multilayer film.

In a case in which the Ta compound contains T and N, the content of N atoms in the Ta compound is preferably 10.0 to 35.0 at %, more preferably 10.0 to 25.0 at %, further preferably 10.5 to 18.0 at %, and particularly preferably 11.0 to 16.0 at %, in order to increase the etching selectivity.

In a case in which the Ta compound contains N, it may further include at least one element selected from hafnium (Hf), silicon (Si), zirconium (Zr), titanium (Ti), germanium (Ge), boron (B), tin (Sn), nickel (Ni), cobalt (Co), and hydrogen (H). The total content of these elements is preferably 10 at % or less.

A film formation method for the absorbing film 13 is, for example, a DC sputtering method, a magnetron sputtering method, an ion beam sputtering method, or the like. The content of nitrogen in the absorbing film 13 can be controlled by adjusting the content of N₂ gas in the sputtering gas.

In a case in which a TaN film is formed using a reactive sputtering method, an example of the film formation conditions is as follows.

### <Film Formation Conditions for TaN Film>

Target: Ta target
Power density of Ta target: 1.0 W/cm² to 8.5 W/cm²
Sputtering gas: mixed gas of Ar gas and N₂ gas
Volume ratio of N₂ gas in sputtering gas (N₂/(Ar+N₂)): 0.01 to 0.25
Gas pressure: 1.0×10⁻² Pa to 1.0×10⁰ Pa
Film formation rate: 0.020 nm/sec to 0.060 nm/sec
Film thickness: 20 nm to 60 nm

It is preferable that the absorbing film 13 have an extremely low reflectance for EUV light. Specifically, the reflectance of the absorbing film 13 for a light ray having a wavelength of 13.5 nm is preferably 2.0% or less, more preferably 1.0% or less, even more preferably 0.5% or less, and particularly preferably 0.1% or less. The absorbing film 13 has a reflectance of 0.0% or more for the light ray having a wavelength of 13.5 nm.

The hard mask film 14 is formed on a side of the absorbing film 13 opposite to the protective film 12 and is used to form the opening pattern 13a in the absorbing film 13. The hard mask film 14 enables the resist film 16 to be made thinner.

The hard mask film 14 preferably includes at least one metal element or metalloid element selected from Al, Hf, Y, Cr, Nb, Ti, Mo, Ta, and Si. The hard mask film 14 preferably includes a compound of the above-described metal element or metalloid element. The compound thereof preferably includes at least one element selected from O, N, C, and B.

The film thickness of the hard mask film 14 is preferably 2 nm or more and 30 nm or less, more preferably 2 nm or more and 25 nm or less, and even more preferably 2 nm or more and 10 nm or less.

A film formation method for the hard mask film 14 is, for example, a DC sputtering method, a magnetron sputtering method, an ion beam sputtering method, or the like.

The conductive film 15 is formed on a side of the substrate 10 opposite to the multilayer reflective film 11 and is used to adsorb the reflective mask 2 to an electrostatic chuck of an exposure device. The conductive film 1S preferably includes at least one metal element selected from Cr and Ta. The conductive film 15 preferably includes a compound of the above-described metal element. The compound thereof preferably includes at least one element selected from O, N, C, and B.

In the present embodiment, the conductive film 15 is a film made of a single layer, but it may be a multilayer film having a lower layer and an upper layer. The lower layer and the upper layer that constitute the conductive film 15 are formed on the substrate 10, in that order. The uppermost layer of the conductive film 15 is a layer farthest from the substrate 10. The uppermost layer of the conductive film 15 preferably includes at least one metal element selected from Cr and Ta, and more preferably includes a compound of the above-described metal element. In a case in which the conductive film 15 is a multilayer film, the thickness of the conductive film 15 means the total film thickness of the multilayer film.

The film thickness of the conductive film 15 is preferably 5 nm or more and 500 nm or less, more preferably 10 nm or more and 450 nm or less, and even more preferably 20 nm or more and 400 nm or less.

A film formation method for the conductive film 15 is, for example, a DC sputtering method, a magnetron sputtering method, an ion beam sputtering method, or the like.

### EXAMPLES

Hereinafter, experimental data will be described. In Examples 1 to 5, the reflective mask blank 1 having the substrate 10, the multilayer reflective film 11, the protective film 12, and the absorbing film 13, in that order, was produced. In Examples 1 to 5, the reflective mask blanks 1 having the same configuration except for the configuration of the protective film 12 were produced. Examples 1 to 5 are examples of the present invention.

As the substrate 10, a SiO₂—TiO₂ based glass substrate (outer size of 6 inch (152 mm) square, thickness of 6.3 mm) was prepared. This glass substrate had a thermal expansion coefficient at 20 °C of 0.02×10⁻⁷~/°C, a Young's modulus of 67 GPa, a Poisson's ratio of 0.17, and a specific rigidity of 3.07×10⁷ m²/s². The quality assurance area of the first main surface 10a of the substrate 10 had a root mean square roughness (Rq) of 0.15 nm or less and a flatness of 100 nm or less through polishing. A Cr film having a thickness of 100 nm was formed on the second main surface 10b of the substrate 10 using a magnetron sputtering method. The sheet resistance of the Cr film was 100 Ω/□.

As the multilayer reflective film 11, a Mo/Si multilayer reflective film was formed. The Mo/Si multilayer reflective film was formed by repeating the process of depositing a Si layer (film thickness: 4.5 nm) and a Mo layer (film thickness: 2.3 nm) 40 cycles using an ion beam sputtering method. The total film thickness of the Mo/Si multilayer reflective film was 272 nm ((4.5 nm+2.3 nm)×40). The uppermost layer of the Mo/Si multilayer reflective film was a Si layer.

As the protective film 12, a RuSiO film (film thickness: 4 nm to 6 nm) having a composition shown in Table 1 was formed. The RuSiO film was formed by forming a RuSi film using a dual sputtering method and subsequently oxidizing the RuSi film with O plasma. The element ratio of Ru to Si in the RuSiO film was adjusted with the power density of each of the Ru target and the Si target. In addition, the O concentration in the RuSiO film was in accordance with the Si concentration. Si was more easily oxidized than Ru, and thus, as the Si concentration was increased, the O concentration was increased.

As the absorbing film 13, a TaN film (40 nm) was formed. The TaN film was formed using a reactive sputtering method.

The experimental conditions and the experimental results of Examples 1 to 5 are shown in Table 1. The concentration of each element constituting the RuSiO film was analyzed using transmission electron microscope—energy dispersive X-ray spectroscopy (TEM-EDX). In addition, the presence or absence of the defect including SiO was checked by observing the surface of the TaN film with a scanning electron microscope (SEM). If the defect including SiO is present at an interface between the RuSiO film and the TaN film, a micro-defect due to the defect including SiO appears on the surface of the TaN film. The amorphous nature of the TaN film, that is, the degree of crystallization of the TaN film, was checked using X-ray diffraction (XRD).

TABLE 1

| | | Exam- | Exam- | Exam- | Exam- | Exam- |
|---|---|---|---|---|---|---|
| | | ple 1 | ple 2 | ple 3 | ple 4 | ple 5 |
| RuSiO | Si | 9.6 | 18.8 | 23.9 | 36.6 | 37.9 |
| film | concentration | | | | | |
| | average | | | | | |
| | value [at %] | | | | | |
| | O | 3.7 | 5.4 | 4.7 | 6.2 | 12.6 |
| | concentration | | | | | |
| | average | | | | | |
| | value [at %] | | | | | |
| | Ru | 86.7 | 75.8 | 71.3 | 57.2 | 49.4 |
| | concentration | | | | | |
| | average | | | | | |
| | value [at %] | | | | | |

| | | | | | |
|---|---|---|---|---|---|
| Amorphous nature of | A | A | A | A | A |
| TaN film | | | | | |
| Presence or absence of | A | A | A | A | B |
| defect including SiO | | | | | |

In Table 1, the fact that the amorphous nature of the TaN film is “A” indicates that the full width at half maximum of the highest intensity peak in the range of 2θ of 20° to 50° measured by an XRD method using CuKα radiation was 1.0° or more, that is, the crystallization of the TaN film could be suppressed. In addition, in Table 1, the fact that the presence or absence of the defect including SiO is “A” indicates that no micro-defect due to the defect including SiO was observed on the surface of the TaN film using the SEM, and the fact that the presence or absence of the defect including SiO is “B” indicates that a micro-defect due to the defect including SiO was observed on the surface of the TaN film using the SEM.

As shown in Table 1, in Examples 1 to 5, the protective film 12 was a RuSiO film, and thus the crystallization of the TaN film, which is the absorbing film 13, could be suppressed. It has also been checked that even in a case in which the material of the absorbing film 13 is an Nb-based material or an Ir-based material, if the protective film 12 is a RuSiO film, the crystallization of the absorber film 13 can be suppressed. In addition, as shown in Table 1, in Examples 1 to 4, unlike Example 5, the Si concentration of the RuSiO film was less than 37.9 at %, and therefore, no micro-defect due to the defect including SiO was observed on the surface of the TaN film using the SEM.

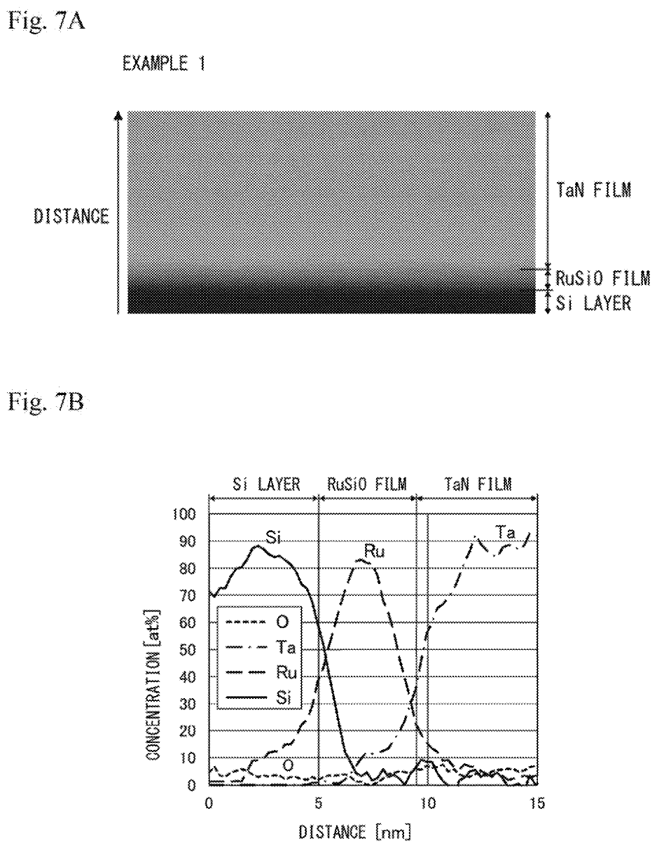

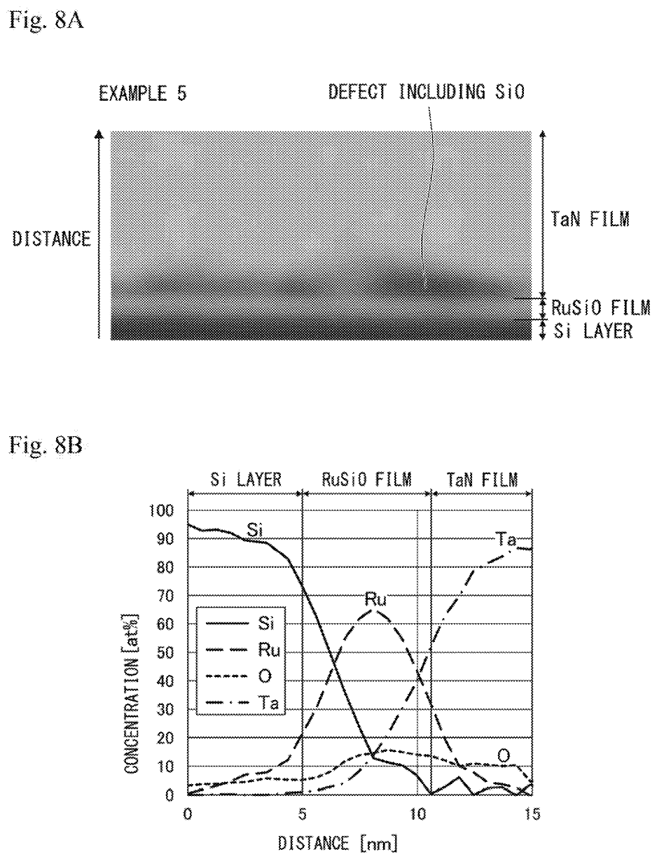

FIG. 7 shows a TEM image of the reflective mask blank according to Example 1 and the distribution of each element thereof measured using the TEM-EDX. In addition, FIG. 8 shows a TEM image of the reflective mask blank according to Example 5 and the distribution of each element thereof measured using the TEM-EDX. As shown in FIG. 8, in Example 5, the defect including SiO was observed at the interface between the RuSiO film and the TaN film, but in Example 1, the defect including SiO was not observed at the interface between the RuSiO film and the TaN film.

In the above, the reflective mask blank, the reflective mask, the method for manufacturing a reflective mask blank, and the method for manufacturing a reflective mask according to the present disclosure have been described, but the present disclosure is not limited to the above-described embodiments. Various changes, modifications, substitutions, additions, deletions, and combinations are possible within the scope of the claims. Naturally, these also fall within the technical scope of the present disclosure.

### BRIEF DESCRIPTION OF THE REFERENCE SYMBOLS

1 Reflective mask blank
2 Reflective mask
10 Substrate
11 Multilayer reflective film
12 Protective film
13 Absorbing film

1. A reflective mask blank comprising: a substrate; a multilayer reflective film that reflects EUV light; a protective film that protects the multilayer reflective film; and an absorbing film that absorbs EUV light, in that order,
wherein the protective film includes a Ru compound, and the Ru compound includes Ru, Si, and O.

2. The reflective mask blank according to claim 1, wherein the Ru compound has an average value of a Si concentration of less than 37.9 at %.

3. The reflective mask blank according to claim 1, wherein the Ru compound has an average value of a Si concentration of 9.0 at % or more.

4. The reflective mask blank according to claim 1, wherein the absorbing film includes at least one metal element selected from Cr, Ta, Nb, Ir, Pt, Pd, Au, and Ru.

5. The reflective mask blank according to claim 2, wherein the absorbing film includes at least one metal element selected from Cr, Ta, Nb, Ir, Pt, Pd, Au, and Ru.

6. The reflective mask blank according to claim 3, wherein the absorbing film includes at least one metal element selected from Cr, Ta, Nb, Ir, Pt, Pd, Au, and Ru.

7. The reflective mask blank according to claim 4,
wherein the absorbing film includes a compound of the metal element, and
wherein the compound of the metal element includes at least one element selected from O, B, C, Si, and N.

8. The reflective mask blank according to claim 5,
wherein the absorbing film includes a compound of the metal element, and
wherein the compound of the metal element includes at least one element selected from O, B, C, Si, and N.

9. The reflective mask blank according to claim 6,
wherein the absorbing film includes a compound of the metal element, and
wherein the compound of the metal element includes at least one element selected from O, B, C, Si, and N.

10. The reflective mask blank according to claim 7, wherein the absorbing film includes a Ta compound, and the Ta compound includes N.

11. The reflective mask blank according to claim 8, wherein the absorbing film includes a Ta compound, and the Ta compound includes N.

12. The reflective mask blank according to claim 9, wherein the absorbing film includes a Ta compound, and the Ta compound includes N.

13. The reflective mask blank according to claim 10, wherein a content of N atoms in the Ta compound is 10.0 at % or more and 35.0 at % or less.

14. The reflective mask blank according to claim 11, wherein a content of N atoms in the Ta compound is 10.0 at % or more and 35.0 at % or less.

15. The reflective mask blank according to claim 12, wherein a content of N atoms in the Ta compound is 10.0 at % or more and 35.0 at % or less.

16. A reflective mask comprising the reflective mask blank according to claim 1,
wherein an opening pattern is included in the absorbing film.

17. A method for manufacturing a reflective mask blank, comprising forming, on a substrate, a multilayer reflective film that reflects EUV light, a protective film that protects the multilayer reflective film, and an absorbing film that absorbs EUV light, in that order,
wherein the protective film includes a Ru compound, and the Ru compound includes Ru, Si, and O.

18. A method for manufacturing a reflective mask, comprising:
preparing the reflective mask blank according to claim 1; and
forming an opening pattern in the absorbing film,
in that order.
